(19) United States
(12) Patent Application Publication
(10) Pub. No.: US 2014/0232386 A1
(43) Pub. Date: Aug. 21, 2014

(54) CURRENT DETECTION DEVICE

(71) Applicant: Tatsuyuki Yamaguchi, Toyota-shi (JP)

(72) Inventor: Tatsuyuki Yamaguchi, Toyota-shi (JP)

(73) Assignees: KABUSHIKI KAISHA TOKAI RIKA DENKI SEISAKUSHO, Niwa-gun, Aichi (JP); TOYOTA JIDOSHA KABUSHIKI KAISHA, Toyota-shi, Aichi-ken (JP)

(21) Appl. No.: 14/346,480

(22) PCT Filed: Sep. 18, 2012
(86) PCT No.: PCT/IB2012/001805

§ 371 Date: Mar. 21, 2014

(30) Foreign Application Priority Data
Sep. 26, 2011 (JP) 2011-209871

(51) Int. Cl. G01R 19/00; G01R 33/09; G01R 33/07

(52) U.S. Cl. CPC G01R 19/0092; G01R 33/07; G01R 33/093
USPC 324/247

(57) ABSTRACT

A first bent portion whose extending direction changes in the order of +z, +x, +z, −x, and +z is formed in a first current path, wherein a direction in which two current paths extend in parallel as the z-direction of the x-y-z orthogonal coordinate system and a second bent portion whose extending direction changes in the order of +z, +y, +z, −y, and +z is formed in a second current path. Either one of the z-coordinate range of the middle part of the first bent portion and the z-coordinate range of the middle part of the second bent portion includes the other one and a magnetic flux density detection device that detects the x-direction magnetic flux density and the y-direction magnetic flux density is disposed within the included z-coordinate region.

### BACKGROUND OF THE INVENTION

1. Field of the Invention

The present invention provides a technique that independently detects the value of a current passing through each of two current paths that extend in parallel. In other words, the invention provides a technique that detects the value of a current passing through a first current path (hereinafter referred to as a first current value) without being affected by a current passing through a second current path and detects the value of the current passing through the second current path (hereinafter referred to as a second current value) without being affected by the current passing through the first current path when the first current path and the second current path extend in parallel. When three-phase alternating currents are passed through three current paths, the value of a current passing through a third current path (hereinafter referred to as a third current value) can be calculated from the first current value and second current value. The present technique can be applied to the three-phase alternating current to detect current values in three phases (U-phase, V-phase and W-phase).

2. Description of Related Art

When the value of a current passing through each of two current paths that extend in parallel is detected, generally the detection of the first current value is affected by the current passing through the second current path and the detection of the second current value is affected by the current passing through the first current path.

In Japanese Patent Application Publication No. 2010-175474 (JP 2010-175474 A), a technique that detects the first current value without being affected by the current passing through the second current path and detects the second current value without being affected by the current passing through the first current path is disclosed. In the technique of JP 2010-175474 A, a portion that extends obliquely is provided in a middle section of each of three current paths disposed in parallel. Hereinafter, the portion that extends obliquely is referred to as an oblique portion and the rest of the current path other than the oblique portion is referred to as a straight portion. A magnetic field is generated around the current path by a current passing through the current path according to the right-handed screw law. Around the current path provided with the oblique portion, both a magnetic field generated by the current of the oblique portion and a magnetic field generated by the current of the straight portion are formed. By providing the oblique portion in the current path, a region where both the magnetic field by the current passing through the oblique portion and the magnetic field by the current passing through the straight portion are not formed can be obtained. In other words, a gap region where distribution of the magnetic field is suppressed can be obtained.

In the technique of JP 2010-175474 A, a first magnetic flux density detection device is arranged in a region that overlaps the gap region of the second current path and the gap region of the third current path and is filled with the magnetic field generated by the first current path. The first magnetic flux density detection device detects a magnetic flux density corresponding to the first current value. The first current value can be detected without being affected by the second current value and the third current value. The same also applies to the second current value. A second magnetic flux density detection device is arranged in a region that overlaps the gap region of the third current path and the gap region of the first current path and is filled with the magnetic field generated by the second current path. The second magnetic flux density detection device detects a magnetic flux density corresponding to the second current value. The second current value can be detected without being affected by the third current value and the first current value. The same also applies to the third current value. A third magnetic flux density detection device is arranged in a region that overlaps the gap region of the first current path and the gap region of the second current path and is filled with the magnetic field generated by the third current path. The third magnetic flux density detection device detects a magnetic flux density corresponding to the third current value. The third current value can be detected without being affected by the first current value and the second current value.

The technique of JP 2010-175474 A is also useful for detecting the value of a current passing through each of two current paths. In this case, the first magnetic flux density detection device is arranged in a region that overlaps the gap region of the second current path and is filled with the magnetic field generated by the first current path while the second magnetic flux density detection device is arranged in a region that overlaps the gap region of the first current path and is filled with the magnetic field generated by the second current path. The first current value can be detected by the first magnetic flux density detection device without being affected by the second current value. The second current value can be detected by the second magnetic flux density detection device without being affected by the first current value.

The technique of JP 2010-175474 A is a related-art in which knowledge that a gap region where distribution of the magnetic field is suppressed can be obtained by providing an oblique portion is utilized. However, when the spacing between two current paths is narrow, the extent of a region where the magnetic field by the first current path is distributed becomes narrow, which makes it difficult to arrange the first magnetic flux density detection device in such a narrow region. Likewise, a region where the magnetic field by the second current path is distributed also becomes narrow, which makes it difficult to arrange the second magnetic flux density detection device within the region. Also, the magnetic flux density of the gap region is not zero. A leakage flux is distributed in the gap region. When the spacing between two current paths is narrow, even if the magnetic flux density detection device could be arranged in the region where the magnetic field by the second current path is distributed, effects from the leakage ⁻flux become large.

### SUMMARY OF THE INVENTION

This present invention provides a technique that independently detects the value of a current passing through each of two current paths that extend in parallel. This invention provides a technique in which a bent portion is provided in the current path to achieve a relationship that the magnetic flux direction due to a first current path orthogonally crosses the magnetic flux direction due to a second current path.

A current detection device of one aspect of the present invention is a device for detecting the value of a current passing through each of a first current path and a second current path each having a bent portion and extending in parallel with each other except for the bent portion. An x-direction bent portion whose extending direction changes in the order of +z, +x, +z, −x, and +z is formed as the bent portion in the first current path a direction in which the first current path and the second current path extend in parallel as the z-direction of the x-y-z orthogonal coordinate system. In the second current path, a y-direction bent portion whose extending direction changes in the order of +z, +y, +z, −y, and +z is formed as the bent portion. A y-direction magnetic flux density detection device is disposed in a region that is on an x-z plane to which the x-direction bent portion is included and is positioned between a +x part extending in the +x direction of the first current path and a −x part extending in the −x direction of the first current path. An x-direction magnetic flux density detection device is disposed in a region that is on a y-z plane to which the y-direction bent portion is included and is positioned between a +y part extending in the +y direction of the second current path and a −y part extending in the −y direction of the second current path. The x-direction bent portion and the y-direction bent portion are surrounded by a frame of a magnetic material.

In the current detection device of one aspect of the present invention, either one of the z-coordinate range of a first middle part and the z-coordinate range of a second middle part may include the z-coordinate range of the other one. In this case, a two-component magnetic flux density detection device that detects the magnetic flux density in the x-direction and the magnetic flux density in the y-direction may be disposed in the z-coordinate range of the one included in the z-coordinate range of the other one, wherein a part that extends in the +z direction between the +x part and the −x part in the first current path as the first middle part and a part that extends in the +z direction between the +y part and the −y part in the second current path as the second middle part. When the z-coordinate range of either one of the first middle part and the second middle part is set to be included to the z-coordinate range of the other, a region that is within a first middle region as well as within a second middle region can be obtained, which makes it possible to dispose the x-direction magnetic flux density detection device and the y-direction magnetic flux density detection device at the same position. Instead of separately setting the x-direction magnetic flux density detection device and the y-direction magnetic flux density detection device, a single two-component magnetic flux density detection device that acts as the x-direction magnetic flux density detection device and the y-direction magnetic flux density detection device can be set.

In the current detection device of one aspect of the present invention, the two-component magnetic flux density detection device may be disposed at a position where a line segment connecting the two-component magnetic flux density detection device and the first middle part in an x-y plane orthogonally crosses with a line segment connecting the two-component magnetic flux density detection device and the second middle part in the x-y plane. Or, the two-component magnetic flux density detection device may be disposed on a line at which the x-z plane including the x-direction bent portion crosses with the y-z plane including the y-direction bent portion.

In the current detection device of one aspect of the present invention, the intermediate value of the z-coordinate range of the first middle part may be set equal to the intermediate value of the z-coordinate range of the second middle part. In this case, the two-component magnetic flux density detection device may be disposed at a point where the intermediate values are equal. In this case, the density of the magnetic flux generated by the current passing through the +x part becomes equal to the density of the magnetic flux generated by the current passing through the −x part, thereby increasing the y-direction magnetic flux density at the position of the two-component magnetic flux density detection device. Likewise, the density of the magnetic flux generated by the current passing through the +y part becomes equal to the density of the magnetic flux generated by the current passing through the −y part, thereby increasing the x-direction magnetic flux density at the position of the two-component magnetic flux density detection device. Thus, the detection sensitivity is enhanced.

In the current detection device of one aspect of the present invention, a current path for three-phase alternating current includes a third current path that extends in parallel with the first current path and the second current path. In this case, the first current path, the second current path and the third current path may be disposed in the order of the first current path, the second current path and the third current path in a y-z plane. Also, the direction from the third current path to the first current path may be set to be the +y direction.

In the current detection device of one aspect of the present invention, a frame of a magnetic material may surround the x-direction bent portion and the y-direction bent portion in the y-z plane and the third current path may pass along outside the frame of a magnetic material. Or, the frame of a magnetic material may surround the x-direction bent portion and the y-direction bent portion in the x-y plane and the third current path may pass along outside the frame of a magnetic material.

The current detection device of one aspect of the present invention may include the two-component magnetic flux density detection device that includes a first Hall element oriented to detect the magnetic flux density in the x-direction and a second Hall element oriented to detect the magnetic flux density in the y-direction. Or, the two-component magnetic flux density detection device may be provided with a bridge circuit including a plurality of GMR elements.

According to the present invention, when the first current path and the second current path extend in parallel, the value of the current passing through the second current path can be detected without being affected by the current passing through the first current path and the value of the current passing through the first current path can be detected without being affected by the current passing through the second current path.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a perspective view showing an x-direction bent portion of a first current path, a y-direction bent portion of a second current path, a third current path and a two-component magnetic flux density detection device;

FIG. 2A shows a direction of a magnetic flux generated by a current passing through the x-direction bent portion of the first current path;

FIG. 2B shows a direction of a magnetic flux generated by a current passing through the y-direction bent portion of the second current path;

FIG. 3A shows a direction of the magnetic field when the x-direction bent portion and the y-direction bent portion are viewed from the z-direction;

FIG. 3B shows a direction of the magnetic field when the x-direction bent portion is viewed from the y-direction;

FIG. 3C shows a direction of the magnetic field when the y-direction bent portion is viewed from the x-direction;

FIG. 4 schematically shows how a frame of a magnetic material affects the external magnetic field;

FIG. 5 shows the two-component magnetic flux density detection device including a first Hall element oriented to detect the magnetic flux density in the x-direction and a second Hall element oriented to detect the magnetic flux density in the y-direction;

FIG. 6 shows a two-component magnetic flux density detection device provided with a bridge circuit including a plurality of GMR elements;

FIG. 7A exemplifies the relationship among the x-direction bent portion of the first current path, the y-direction bent portion of the second current path, and the third current path;

FIG. 7B exemplifies the relationship among the x-direction bent portion of the first current path, the y-direction bent portion of the second current path, and the third current path;

FIG. 7C exemplifies the relationship among the x-direction bent portion of the first current path, the y-direction bent portion of the second current path, and the third current path;

FIG. 8 shows a current detection circuit having a frame according to a second embodiment; and

FIG. 9 shows a current detection circuit having a frame according to a third embodiment.

### DETAILED DESCRIPTION OF EMBODIMENTS

First, the primary features of the embodiments shown below are listed. A current path is made of a metal band (bus bar). Current paths are arranged in the order corresponding to a first current path, a second current path and a third current path. The direction in which each of the first current path, the second current path and the third current path extends is defined as the z-direction. The direction starting from the third current path and heading toward the first current path via the second current path is defined as the y-direction. An x-direction bent portion is formed in the first current path and a y-direction bent portion is formed in the second current path. The y-direction bent portion extends beyond the first current path in a y-z plane. The x-direction bent portion intrudes inside the y-direction bent portion. A two-component magnetic flux density detection device is disposed inside of the x-direction bent portion. The two-component magnetic flux density detection device is disposed in a position that overlaps the first current path in a y-z plane. The distance from the two-component magnetic flux density detection device to a +x part (a part of the x-direction bent portion extending in the +x direction) is equal to the distance from the two-component magnetic flux density detection device to a −x part (a part of the x-direction bent portion extending in the −x direction). The distance from the two-component magnetic flux density detection device to a +y part (a part of the y-direction bent portion extending in the +y direction) is equal to the distance from the two-component magnetic flux density detection device to a −y part (a part of the y-direction bent portion extending in the −y direction). The length of the +x part is equal to the length of the −x part. The length of the +y part is equal to the length of the −y part.

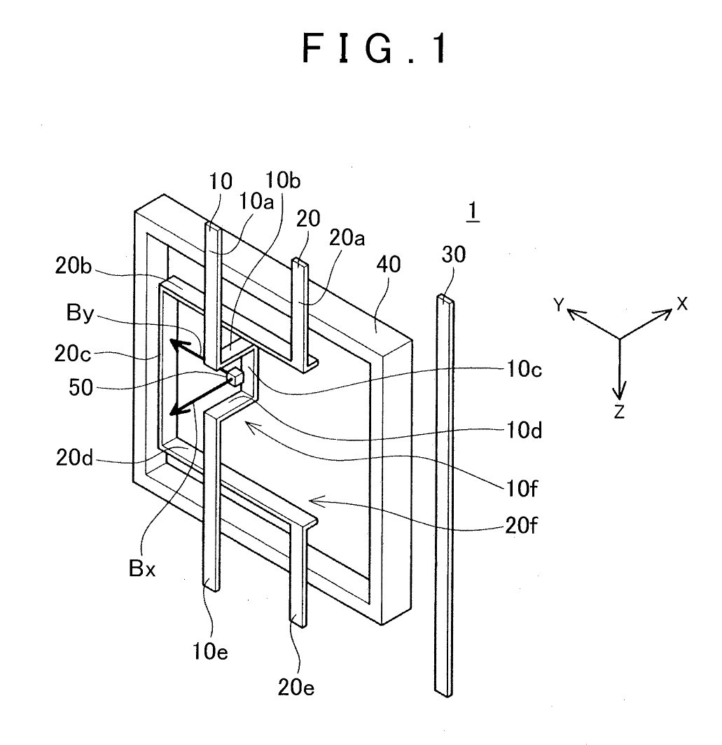

FIG. 1 shows three current paths each carrying a three-phase alternating current. In other words, a first current path 10, a second current path 20 and a third current path 30 are shown. A U-phase current flows in the first current path 10, a V-phase current flows in the second current path 20, and a W-phase current flows in the third current path 30. A current detection device 1 shown in FIG. 1 detects the value of a current passing through the first current path 10 (hereinafter referred to as a first current value) and the value of a current passing through the second current path 20 (hereinafter referred to as a second current value) with a two-component magnetic flux density detection device 50. In the case of three-phase alternating current, if the current value of the U-phase (first current value) and the current value of the V-phase (second current value) are detected, the current value of the W-phase (third current value of the third current path) can be determined. Thus, the current detection device 1 shown in FIG. 1 fulfills a function as a device that detects each of the first current value (U-phase current value), the second current value (V-phase current value) and the third current value (W-phase current value).

Each of the first current path 10, the second current path 20 and the third current path 30 is made of a metal band (bus bar) with low resistivity. Longitudinal direction for each of bus bars is coincided and is defined as the z direction. Hereinafter, the direction from top to bottom in the drawing sheet of FIG. 1 is defined as the +z direction. The direction starting from the third current path 30 and heading toward the first current path 10 via the second current path 20 is defined as the +y direction. The direction orthogonal to the y-direction and the z-direction is defined as the x-direction. Specifically, the direction heading toward right and back in the drawing sheet of FIG. 1 is defined as the +x direction. The first current path 10, the second current path 20 and the third current path 30 are arranged in a y-z plane.

Looking the first current path 10 from top to bottom in the drawing sheet of FIG. 1, it is found that a part 10a extending in the +z direction, a part 10b extending in the +x direction (+x part), a part 10c extending in the +z direction (first middle part), a part 10d extending in the −x direction (−x part), and a part 10e extending in the +z direction are continuously connected in this order. An x-direction bent portion 10f is formed of these parts. Looking the second current path 20 from top to bottom, it is found that a part 20a extending in the +z direction, a part 20b extending in the +y direction (+y part), a part 20c extending in the +z direction (second middle part), a part 20d extending in the −y direction (−y part), and a part 20e extending in the +z direction are continuously connected in this order. A y-direction bent portion 20f is formed of these parts. The y-direction bent portion 20f extends beyond the first current path 10 in a y-z plane. The third current path 30 uniformly extends in the +z direction and has no bent portion. At this time, when the heading direction of the x-direction bent portion changes in the order of +z, +x, +z, −x and +z, the direction may change sharply or gradually. Sharp change makes a rectangular bent portion and gradual change makes a U-shape bent portion respectively. The same applies to the y-direction bent portion.

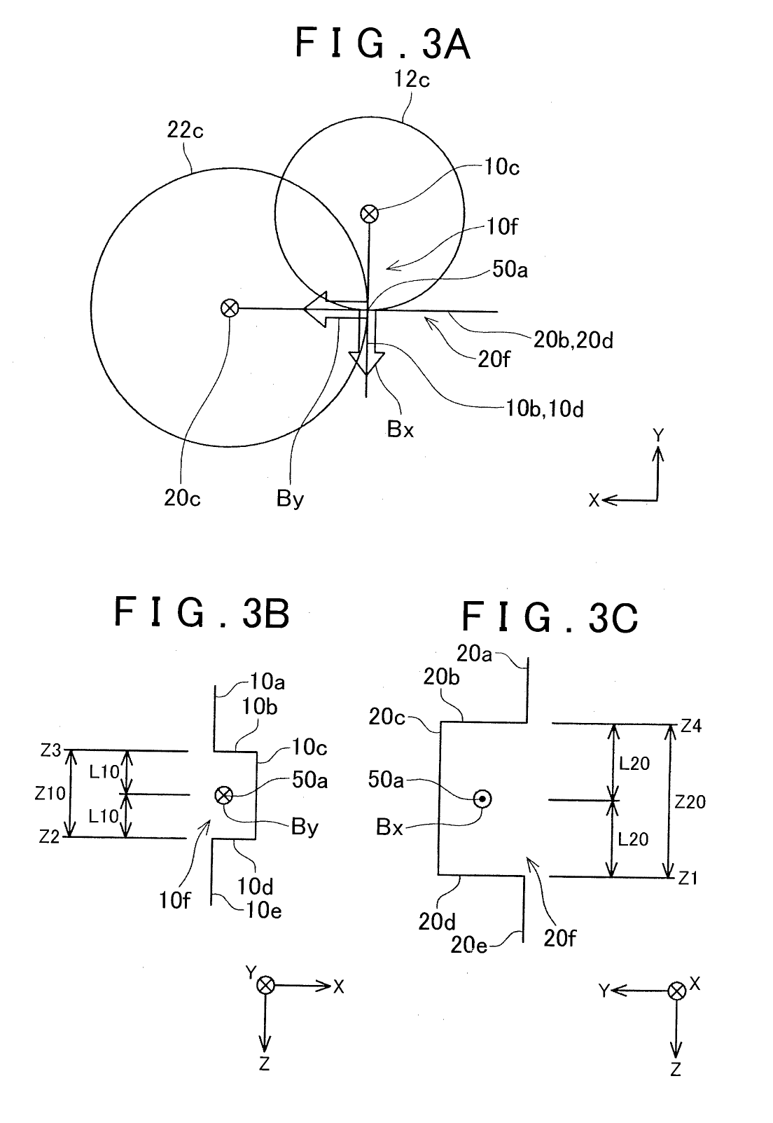

FIG. 3B is a view of the x-direction bent portion 10f seen from the y-direction. The first middle part 10c extends in a first z-coordinate range z10 (between z2 and z3). FIG. 3C is a view of the y-direction bent portion 20f seen from the x-direction. The second middle part 20c extends in a second z-coordinate range z20 (between z1 and z4). Here, z1>z2>z3>z4. The first z-coordinate range z10 (between z2 and z3) is included in the second z-coordinate range z20 (between z1 and Z4). As described above, the y-direction bent portion 20f extends beyond the first current path 10 in a y-z plane. As a result, the x-direction bent portion 10f intrudes inside the y-direction bent portion 20f.

The two-component magnetic flux density detection device 50 is disposed in a region between the +x part 10b and the −x part 10d as well as on an x-z plane that includes the x-direction bent portion 10f. At the same time, the two-component magnetic flux density detection device 50 is disposed in a region between the +y part 20b and the −y part 20d as well as on a y-z plane that includes the y-direction bent portion 20f.

As shown in FIG. 3B, a distance L10 from a position 50a in which the two-component magnetic flux density detection device 50 is disposed to the +x part 10b is equal to the distance L10 from the position 50a to the −x part 10d. The z-coordinate of the position 50a corresponds to an intermediate value (z2+z3)/2 of the first z-coordinate range z10 (between z2 and z3) and is within the first z-coordinate range z10. As shown in FIG. 3C, a distance L20 from the position 50a to the +y part 20b is equal to the distance L20 from the position 50a to the −y part 20d. The z-coordinate of the position 50a corresponds to an intermediate value (z1+z4)/2 of the second z-coordinate range z20 (between z1 and z4) and is within the second z-coordinate range z20. The intermediate values are set as: (z2+z3)/2=(z1+z4)/2.

FIG. 3A is a view of the x-direction bent portion 10f and the y-direction bent portion 20f seen from the z-direction. The position 50a is disposed on a line at which an x-z plane including the x-direction bent portion 10f crosses with a y-z plane including the y-direction bent portion 20f. Further, when looking in an x-y plane, the two-component magnetic flux density detection device 50 is disposed at a position where the relationship that a line segment connecting the position 50a and the first middle part 10c orthogonally crosses with a line segment connecting the position 50a and the second middle part 20c can be obtained.

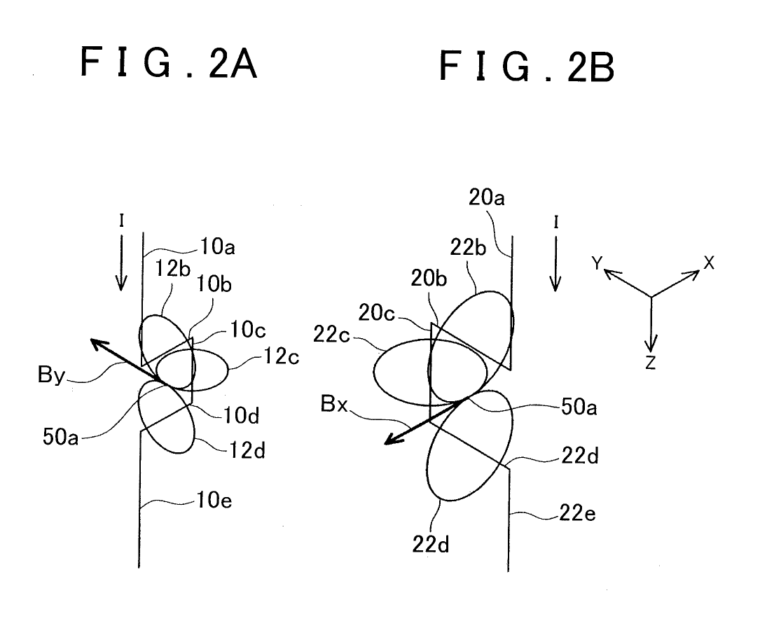

FIG. 2A shows a magnetic flux 12b generated by the current passing through the +x part 10b, a magnetic flux 12c generated by the current passing through the first middle part 10c, and a magnetic flux 12d generated by the current passing through the −x part 10d. At the position 50a, the magnetic flux 12b, the magnetic flux 12c and the magnetic flux 12d all point to the +y direction, which can also be confirmed by the FIG. 3A. At the position 50a, a strong magnetic flux By is generated by the superposition of the magnetic flux 12b, the magnetic flux 12c and the magnetic flux 12d that point to the same direction. FIG. 2B shows a magnetic flux 22b generated by the current passing through the +y part 20b, a magnetic flux 22c generated by the current passing through the second middle part 20c, and a magnetic flux 22d generated by the current passing through the −y part 20d. At the position 50a, the magnetic flux 22b, the magnetic flux 22c and the magnetic flux 22d all point to the −x direction, which can also be confirmed by the FIG. 3A. At the position 50a, a strong magnetic flux Bx is generated by the superposition of the magnetic flux 22b, the magnetic flux 22c and the magnetic flux 22d that point to the same direction. Here, a region that is on an x-z plane to which the x-direction bent portion is included and is surrounded by the +x part and −x part is defined as a first middle region. Further, a region that is on a y-z plane to which the y-direction bent portion is included and is surrounded by the +y part and the −y part is defined as a second middle region. The current passing through the x-direction bent portion generates a magnetic flux extending in the y-direction in the first middle region according to the right-handed screw law. Further, the magnetic flux generated by the current of the +x part, the magnetic flux generated by the current passing through a part extending in the +z direction, and the magnetic flux generated by the current of the −x part are superposed in the same direction. Likewise, the current passing through the y-direction bent portion generates a magnetic flux extending in the x-direction in the second middle region according to the right-handed screw law. Further, the magnetic flux generated by the current of the +y part, the magnetic flux generated by the current passing through a part extending in the +z direction, and the magnetic flux generated by the current of the −y part are superposed in the same direction.

If a y-direction magnetic flux density detection device is disposed in the first middle region, the density of the magnetic flux in the y-direction generated by the current passing through the x-direction bent portion is detected. Because the magnetic flux generated by the current passing through y-direction bent portion points to the x-direction and has no y-component, the current passing through the x-direction bent portion (i.e. first current value) can be detected without being affected by the current passing through the y-direction bent portion (i.e. second current value). Further, the y-direction magnetic flux detected by the y-direction magnetic flux density detection device is resulted from the superposition of the magnetic flux generated by the current passing through the +x part, the magnetic flux generated by the current passing through a part extending in the +z direction, and the magnetic flux generated by the current passing through the −x part and therefore has high density. Thus, high detection sensitivity can be achieved. Likewise, if an x-direction magnetic flux density detection device is disposed in the second middle region, the density of the magnetic flux in the x-direction generated by the current passing through the y-direction bent portion is detected. Because the magnetic flux generated by the current passing through x-direction bent portion points to the y-direction and has no x-component, the current passing through the y-direction bent portion (i.e. second current value) can be detected without being affected by the current passing through the x-direction bent portion (i.e. first current value). Further, the x-direction magnetic flux detected by the x-direction magnetic flux density detection device is resulted from the superposition of the magnetic flux generated by the current passing through the +y part, the magnetic flux generated by the current passing through the part extending in the +z direction, and the magnetic flux generated by the current passing through the −y part and therefore has high density. Thus, high detection sensitivity can be achieved. In addition, the x-direction bent portion and the y-direction bent portion are surrounded by a frame of a magnetic material and are therefore protected from false detection due to the effects of an external magnetic field.

When the z-coordinate of the position 50a is set to (z2+z3)/2, the magnetic flux 12b generated at the position 50a by the current passing through the +x part 10b is equal to the magnetic flux 12d generated at the position 50a by the current passing through the −x part 10d. If the z-coordinate of the two-component magnetic flux density detection device 50 is not equal to (z2+z3)/2, the magnetic flux 12b is not equal to the magnetic flux 12d. Comparing the aforementioned two cases, the former has a higher magnetic flux density of the superposition of the magnetic flux 12b and the magnetic flux 12d than the latter. In this embodiment, the two-component magnetic flux density detection device 50 is disposed at a position where the maximum magnetic flux density to the same current value can be obtained.

When the z-coordinate of the position 50a is set to (z1+z4)/2, the magnetic flux 22b generated at the position 50a by the current passing through the +y part 20b is equal to the magnetic flux 22d generated at the position 50a by the current passing through the −y part 20d. If the z-coordinate of the two-component magnetic flux density detection device 50 is not equal to (z1+z4)/2, the magnetic flux 22b is not equal to the magnetic flux 22d. Comparing the aforementioned two cases, the former has a higher magnetic flux density of the superposition of the magnetic flux 22b and the magnetic flux 22d than the latter. In this embodiment, the two-component magnetic flux density detection device 50 is disposed at a position where the maximum magnetic flux density to the same current value can be obtained.

The magnetic flux By in the y-direction at the position 50a is generated only by the current passing through the x-direction bent portion 10f without being affected by the current passing through the y-direction bent portion 20f. This is because the current passing through the y-direction bent portion 20f only generates the magnetic flux Bx in the x-direction and does not generate a y-direction component at the position 50a. Likewise, the magnetic flux Bx in the x-direction at the position 50a is generated only by the current passing through the y-direction bent portion 20f without being affected by the current passing through the x-direction bent portion 10f. This is because the current passing through the x-direction bent portion 10f only generates the magnetic flux By in the y-direction and does not generate an x-direction component at the position 50a. Therefore, the current passing through the x-direction bent portion 10f can be detected by detecting the magnetic flux By. The current passing through the y-direction bent portion 20f does not affect the detection result. Likewise, the current passing through the y-direction bent portion 20f can be detected by detecting the magnetic flux Bx. The current passing through the x-direction bent portion 10f does not affect the detection result. Thus, the first current value does not affect the detection result of the second current value and the second current value does not affect the detection result of the first current value.

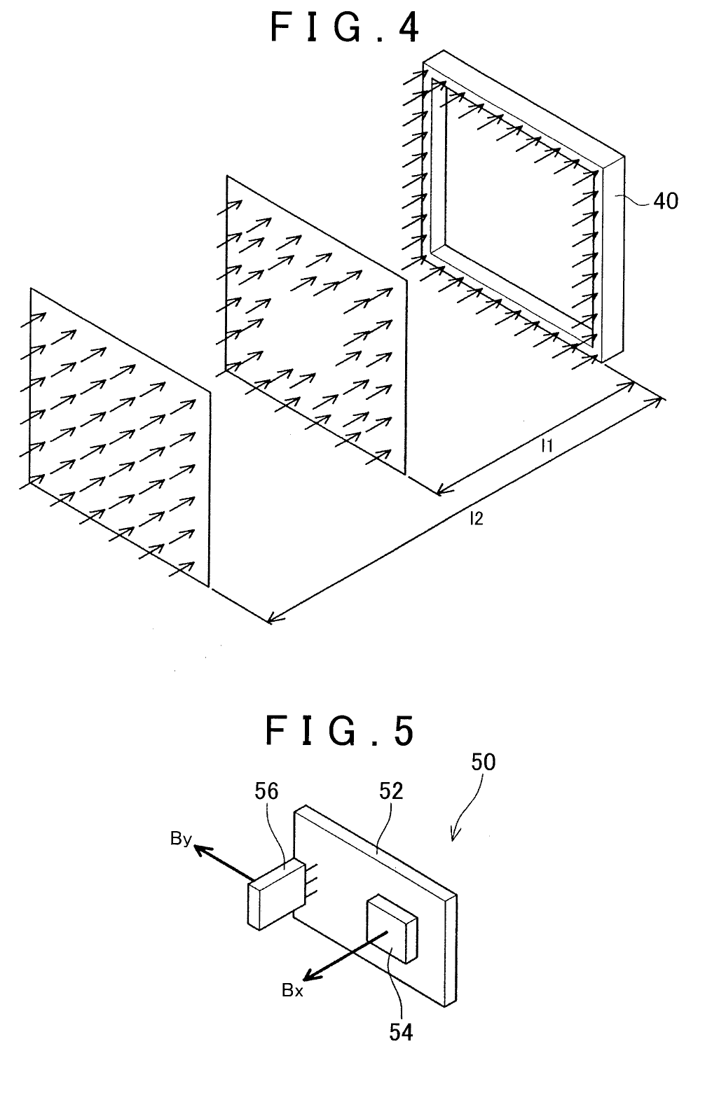

As shown in FIG. 1, a frame 40 of a magnetic material surrounds the x-direction bent portion 10f and the y-direction bent portion 20f. The third current path 30 is positioned outside the frame 40. FIG. 4 schematically shows the effects of the frame 40 of a magnetic material against the external magnetic field. When approaching to the frame 40, the external magnetic field is absorbed by the frame 40. The external magnetic field does not reach the position where the two-component magnetic flux density detection device 50 is disposed. The third current path 30 is positioned outside the frame 40 and the magnetic field generated by a current passing through the third current path 30 corresponds to the external magnetic field shown in FIG. 4. Therefore, the current passing through the third current path 30 does not affect the detection result of the first current value and the second current value. That is, when the two-component magnetic flux density detection device 50 is surrounded by the frame 40 of a magnetic material, the x-direction bent portion 10f and the y-direction bent portion 20f are also surrounded by the frame 40 of a magnetic material. The two-component magnetic flux density detection device 50 is shielded from the external magnetic field by surrounding the x-direction bent portion 10f and the y-direction bent portion 20f with the frame 40 of a magnetic material.

FIG. 5 shows an example of the two-component magnetic flux density detection device 50. The exemplified device includes a first Hall element 56 oriented to detect the magnetic flux By and a second Hall element 54 oriented to detect the magnetic flux Bx both of which are fixed by a circuit board 52 for keeping a relative positional relationship. The first Hall element 56 detects the magnetic flux By to detect the first current value and the second Hall element 54 detects the magnetic flux Bx to detect the second current value.

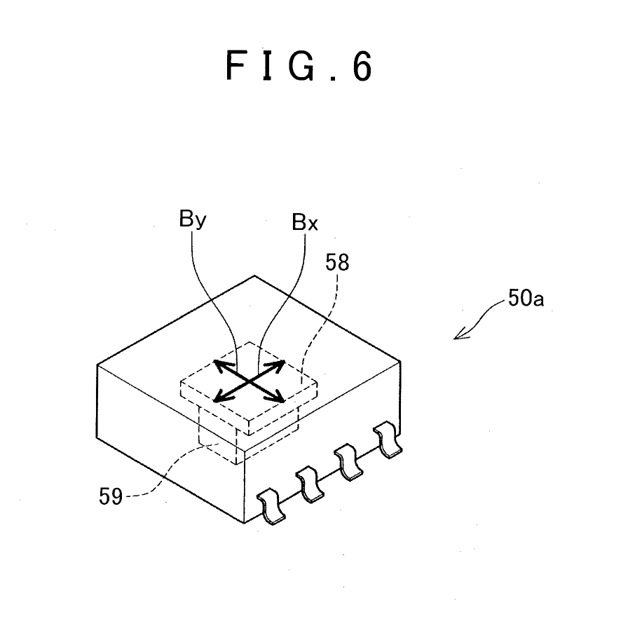

FIG. 6 shows another example of the two-component magnetic flux density detection device 50. Details of the exemplified device are disclosed in Japanese Patent Application Publication No. 2011-22075 (JP 2011-22075 A). What is denoted by 59 in FIG. 6 is a bias magnet and another one by 58 is a circuit board. In the circuit board 58, a bridge circuit utilizing a plurality of GMR elements (resistor element capable of exerting a Giant Magneto Resistive effect) is formed. The two-component magnetic flux density detection device 50a can independently detect the magnetic flux By and the magnetic flux Bx.

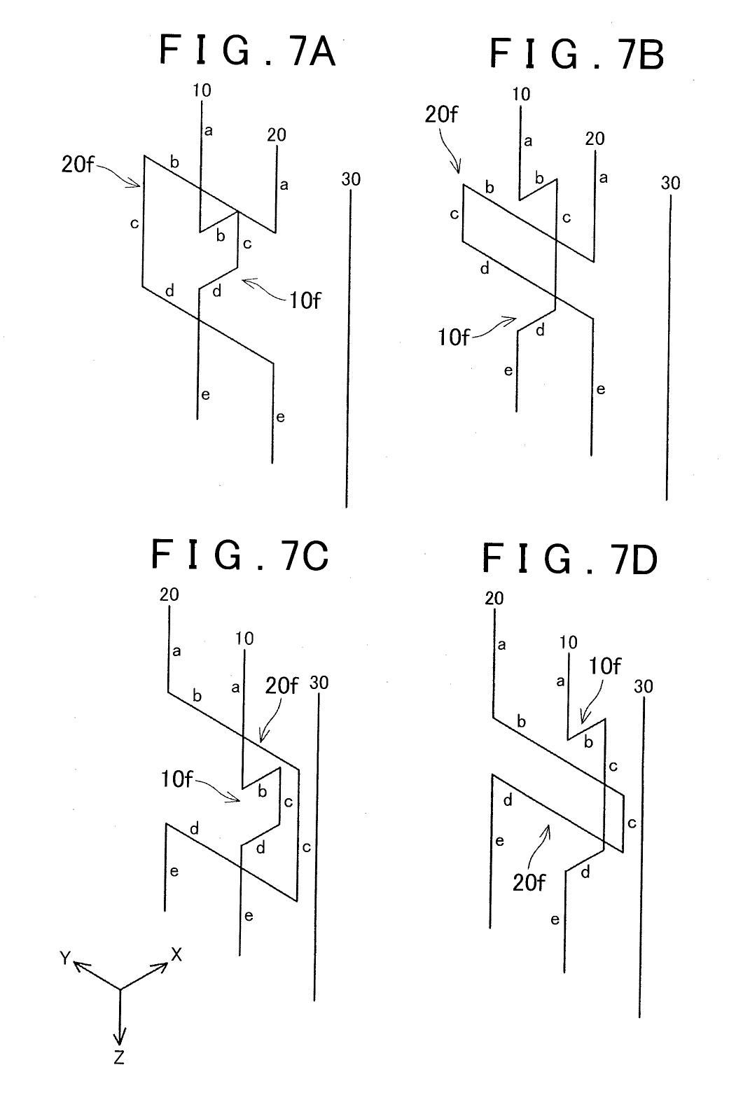

FIG. 7A to FIG. 7D show a various combination of the x-direction bent portion and the y-direction bent portion. FIG. 7A corresponds to the arrangement shown in FIG. 1. FIG. 7B shows an arrangement in which the z-coordinate range of the x-direction bent portion 10f includes the z-coordinate range of the y-direction bent portion 20f and the y-direction bent portion 20f intrudes inside of the x-direction bent portion 10f. FIG. 7C and FIG. 7D show examples in which the first current path 10 having formation of the x-direction bent portion 10f is disposed between the second current path 20 having formation of the y-direction bent portion 20f and the third current path 30. FIG. 7C shows an arrangement in which the z-coordinate range of the y-direction bent portion 20f includes the z-coordinate range of the x-direction bent portion 10f and the x-direction bent portion 10f intrudes inside of the y-direction bent portion 20f. FIG. 7D shows an arrangement in which the z-coordinate range of the x-direction bent portion 10f includes the z-coordinate range of the y-direction bent portion 20f and the y-direction bent portion 20f intrudes inside of the x-direction bent portion 10f.

In any of FIG. 7A to FIG. 7D: (1) the intermediate value of the z-coordinate range of the x-direction bent portion 10f is set equal to the intermediate value of the z-coordinate range of the y-direction bent portion 20f, and the two-component magnetic flux density detection device 50 is disposed at the position of the intermediate value. (2) The two-component magnetic flux density detection device 50 is disposed on a line segment at which an x-z plane including the x-direction bent portion 10f crosses with a y-z plane including the y-direction bent portion 20f. (3) As a result of (2), a line segment connecting the two-component magnetic flux density detection device 50 and the first middle part 10c in an x-y plane orthogonally crosses with a line segment connecting the two-component magnetic flux density detection device 50 and the second middle part 20c in an x-y plane. If the above conditions are met, all of the direction of the magnetic flux generated by the current passing through the +x part 10b, the direction of the magnetic flux generated by the first middle part 10c and the direction of the magnetic flux generated by the current passing through the −x part 10d at the position of the two-component magnetic flux density detection device 50 are the +y direction. In the case of FIG. 7A and FIG. 7B, all of the direction of the magnetic flux generated by the current passing through the +y part 20b, the direction of the magnetic flux generated by the second middle part 20c and the direction of the magnetic flux generated by the current passing through the −y part 20d at the position of the two-component magnetic flux density detection device 50 are the −x direction. In the case of FIG. 7C and FIG. 7D, all of the direction of the magnetic flux generated by the current passing through the −y part 20b, the direction of the magnetic flux generated by the second middle part 20c and the direction of the magnetic flux generated by the current passing through the +y part 20d at the position of the two-component magnetic flux density detection device 50 are the +x direction. In all the cases in FIG. 7A to FIG. 7D, the magnetic flux generated by the current passing through the x-direction bent portion 10f has only a y-component (and no x-component) and the magnetic flux generated by the current passing through the y-direction bent portion 20f has only an x-component (and no y-component) at the position of the two-component magnetic flux density detection device 50. If the magnetic flux density in the y-direction is detected with the two-component magnetic flux density detection device 50, the current passing through the x-direction bent portion 10f can be detected without being affected by the current passing through the y-direction bent portion 20f. Likewise, if the magnetic flux density in the x-direction is detected with the two-component magnetic flux density detection device 50, the current passing through the y-direction bent portion 20f can be 20, detected without being affected by the current passing through the x-direction bent portion 10f. In any of FIG. 7A to FIG. 7D, the direction of the magnetic flux by the +x part 10b is equal to the direction of the magnetic flux by the −x part 10d and the density of the superposed magnetic fluxes are detected, which achieves a high detection sensitivity of the first current value. Also, the direction of the magnetic flux by the +y part is equal to the direction of the magnetic flux by the −y part and the density of the superposed magnetic fluxes are detected, which achieves a high detection sensitivity of the second current value. Further, according to FIG. 7A and FIG. 7B, the distance from the third current path 30 to the two-component magnetic flux density detection device 50 can be lengthened. This suppresses the effects of the magnetic flux generated by the third current path 30.

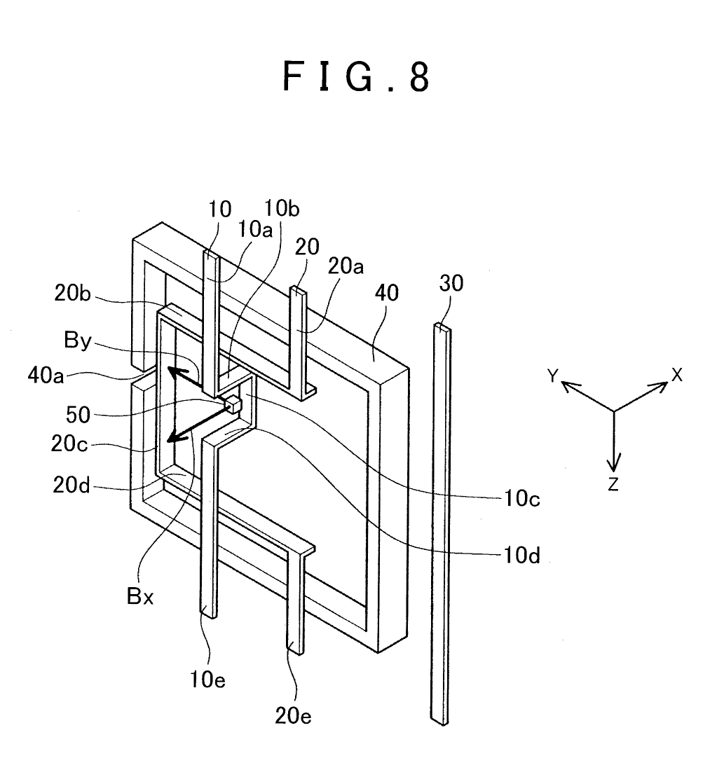

FIG. 8 shows a second embodiment of the frame 40 that shields the two-component magnetic flux density detection device 50 from the external magnetic field. This frame 40 does not make a closed loop and has a gap 40a. Despite the presence of the gap 40a, most of the external magnetic field can be shielded. If the presence of the gap 40a is allowed, a manufacturing process of the frame 40 can be simplified.

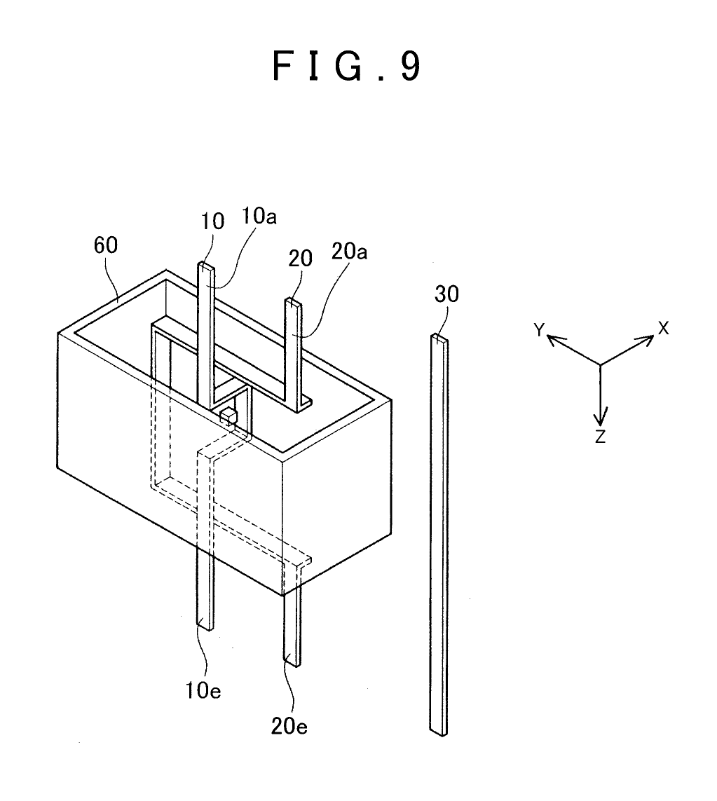

In FIG. 1 and FIG. 8, the frame 40 surrounds the x-direction bent portion 10f and the y-direction bent portion 20f in a y-z plane. In contrast, as shown in FIG. 9, a frame 60 that surrounds the x-direction bent portion 10f and the y-direction bent portion 20f in an x-y plane may be used

While specific examples of the present invention have been described above, these examples are merely illustrative purpose and not intended to limit the claims. Techniques that are disclosed in the claims of the present invention are intended to cover various modifications and changes of the example embodiments that are described above. In addition, the technical elements that are disclosed in the specification or the drawings exhibit technical usefulness alone or in various combinations and configurations, and those are not limited to the combinations and configurations that are disclosed in the claims at the time of filing this application. The techniques that are illustrated in the specification and the drawings can achieve a plurality of objects simultaneously, and the achievement of one object thereof itself has technical usefulness.

1. A current detection device that detects the value of a current passing through each of a first current path and a second current path each having a bent portion and extending in parallel except for the bent portion, comprising:
an x-direction bent portion whose extending direction changes in the order of +z, +x, +z, −x, and +z, formed as the bent portion in the first current path, wherein a direction in which the fiat current path and the second current path extend in parallel is the z-direction of the x-y-z orthogonal coordinate system;
a y-direction bent portion whose extending direction changes in the order of +z, +y, +z, −y, and +z, formed as the bent portion in the second current path;
a y-direction magnetic flux density detection device disposed in a region that is on an x-z plane to which the x-direction bent portion is included and is positioned between a +x part extending in the +x direction of the first current path and a −x part extending in the −x direction of the first current path;
an x-direction magnetic flux density detection device disposed in a region that is on a y-z plane to which the y-direction bent portion is included and is positioned between a +y part extending in the +y direction of the second current path and a −y part extending in the −y direction of the second current path; and
a frame of a magnetic material that surrounds the x-direction bent portion and the y-direction bent portion.

2. The current detection device according to claim 1, wherein
either one of the z-coordinate range corresponding to a first middle part and the z-coordinate range corresponding to a second middle part includes the other one and a two-component magnetic flux density detection device that detects the magnetic flux density in the x-direction and the magnetic flux density in the y-direction is disposed within the z-coordinate range included by the other z-coordinate range, wherein a part that extends in the +z direction between the +x part and the −x part in the first current path is the first middle part and wherein a part that extends in the +z direction between the +y part and the −y part in the second current path is the second middle part.

3. The current detection device according to claim 2, wherein the two-component magnetic flux density detection device is disposed at a position where a line segment connecting the two-component magnetic flux density detection device and the first middle part in an x-y plane orthogonally crosses with a line segment connecting the two-component magnetic flux density detection device and the second middle part in the x-y plane.

4. The current detection device according to claim 3, wherein the two-component magnetic flux density detection device is disposed on a line at which the x-z plane including the x-direction bent portion crosses with the y-z plane including the y-direction bent portion.

5. The current detection device according to claim 4, wherein the intermediate value of the z-coordinate range of the first middle part is set equal to the intermediate value of the z-coordinate range of the second middle part and the two-component magnetic flux density detection device is disposed at a point where the intermediate values are equal.

6. The current detection device according to claim , wherein a third current path that extends in parallel with the first current path and the second current path is provided, the first current path, the second current path and the third current path are disposed in the order of the first current path, the second current path and the third current path in the y-z plane, and the direction from the third current path to the first current path is the +y direction.

7. The current detection device according to claim 6, wherein the frame of a magnetic material surrounds the x-direction bent portion and the y-direction bent portion in the y-z plane, and
the third current path passes along outside the frame of a magnetic material.

8. The current detection device according to claim 6, wherein the frame of a magnetic material surrounds the x-direction bent portion and the y-direction bent portion in the x-y plane and the third current path passes along outside the frame of a magnetic material.

9. The current detection device according to claim 2, wherein the two-component magnetic flux density detection device includes a first Hall element oriented to detect the magnetic flux density in the x-direction and a second Hall element oriented to detect the magnetic flux density in the y-direction.

10. The current detection device according to claim 2, wherein the two-component magnetic flux density detection device is provided with a bridge circuit including a plurality of GMR elements.
